(19) United States
(12) Patent Application Publication
(10) Pub. No.: US 2012/0001046 A1
(43) Pub. Date: Jan. 5, 2012

(54) ADAPTER FOR SUPPORT PROFILES

(75) Inventor: Gerd Schmotz, Bornheim (DE)

(73) Assignee: ENERGIEBAU SOLARSTROMSYSTEME GMBH, (DE)

(21) Appl. No.: 13/256,984

(22) PCT Filed: Mar. 16, 2010
(86) PCT No.: PCT/DE2010/000288

§ 371 Date: Sep. 16, 2011

(30) Foreign Application Priority Data
Mar. 17, 2009 (DE) 20 2009 003 661.8

(51) Int. Cl. H01L 23/12

(52) U.S. Cl. 248/316.1

(57) ABSTRACT

The invention relates to an adapter (1) for support profiles (A), in particular of support arrangements for solar modules, characterized by an assembly head (2) for receiving a support profile (A) comprising at least two opposing legs (4a, 4b) connected by at least one web (3), and at least two mounting clamps (5a, 5b) for the support profile (A) operationally connected to the assembly head (2).

### FIELD OF TECHNOLOGY

Solar panels in particular require a stable and permanent mounting on roofs or other surfaces. Profile rail arrangements on which the solar panels rest and are secured by clamps or brackets, have proven to be effective. Due to wind and/or snow loads, in all kinds of attachment types, high forces act on the individual components of each arrangement. In particular, the respective connections between the individual components are critical. Connections between rails and the underlying support elements are commonly created by screw connections between a side surface of a square profile and a so-called flag, which usually has a holding section of a roof carrier arm that is generally arranged approximately perpendicular to the solar modules.

### BACKGROUND

Thus, for example DE 202 004 019 952 U1 describes a roof carrier element having a base plate for mounting on counter battens or roof rafters, where a U-shaped arm is fastened, which ends in a section with slotted hole, which is perpendicular to the counter battens or rafters, and which is commonly referred to as flag. By means of hammer head screws, the flag can be connected with the side surface of a profile rail. The one-sided and asymmetrical connection of roof carrier and rail has a serious disadvantage. The force load on the structure by wind and/or snow load does not occur evenly, with the consequence that material-wearing torsional forces can take effect.

EP 000001956250 A2 discloses a centric mounting of a profile rail to a fastening section, wherein the profile rail has a centrally arranged thread and the fastening section is provided with strips that are adapted to the profile rail in shape and size. The advantage of a central fixation, favourable for force introduction into the fastening section, stands here against the disadvantage of lack of flexibility. An adjustment of the height distance of the profile rail to the fastening section is just as impossible here as an alignment of the profile rails at right angles to the stabilizing strips. If these are arranged on the fastening section of a roof carrier, depending on the desired alignment of the operationally connected profile rail, roof carriers with different fastening sections must be used. With this, assembly and manufacturing costs are undesirably increased. Crucial for a rapid, reliable and cost-saving mounting of a carrier assembly for solar panels is, besides the possibility of making adjustments in the height gap between support profile and a holder of whatever kind, and the symmetrical force introduction into such a holder, is that the holder can be easily fitted from above with a support profile and also that a correction is possible of the lateral alignment of the support profile with respect to adjacent attachment points. Since each additional step during installation takes time and increases error rates, it is desirable that required fixing or clamping means, such as screws or connectors, are already pre-assembled on the holder, in the absence of the inserted support profile, in order to be merely finally fixed at assembly after positioning the support profile. Furthermore, it is desirable that the connection between support profile and holder, while being sufficiently strong in any selected position, is not accompanied by a plastic deformation of the material, because after such a material-weakening deformation, a correction of the selected position is only possible at the cost of a further weakening of the material. Apart from that, the use of plastic deformable materials would lead to a restriction in the choice of material of both the support profile and holder material.

### SUMMARY

The scope of the present invention is to overcome the above disadvantages of prior art, to enable rapid, secure and cost-saving mounting of a support assembly in the aforementioned sense, to make realisable the described desirable embodiments, and simultaneously provide an adapter that can be generally used when support profiles must be fastened to mounting surfaces.

This is achieved through an adapter according to the invention.

### BRIEF DESCRIPTION

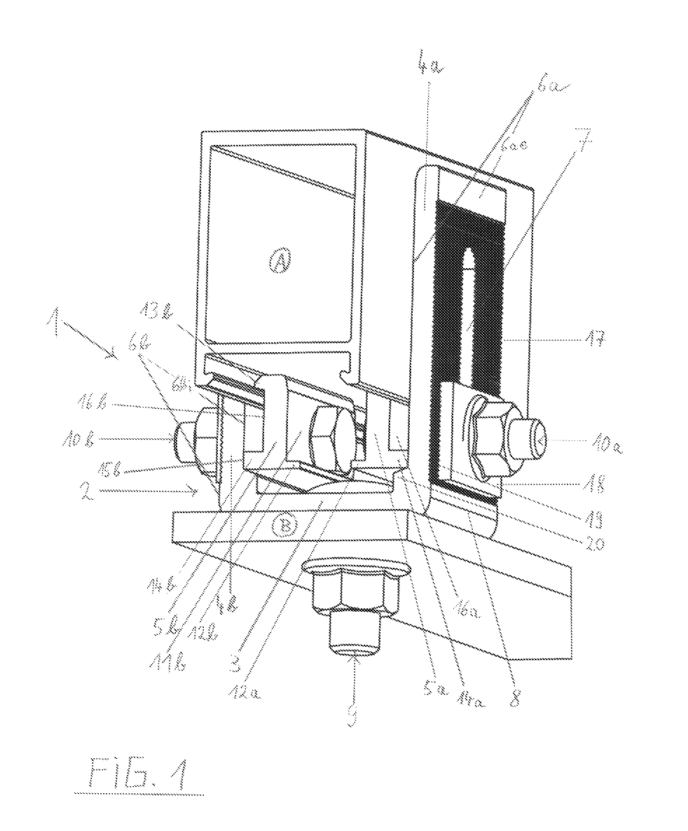

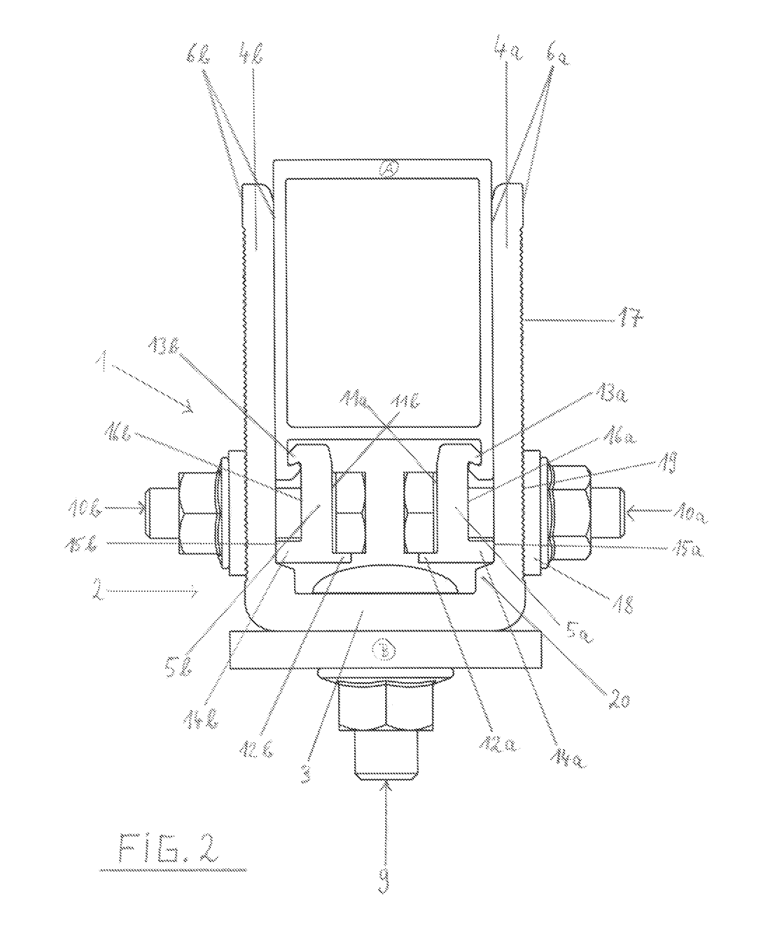

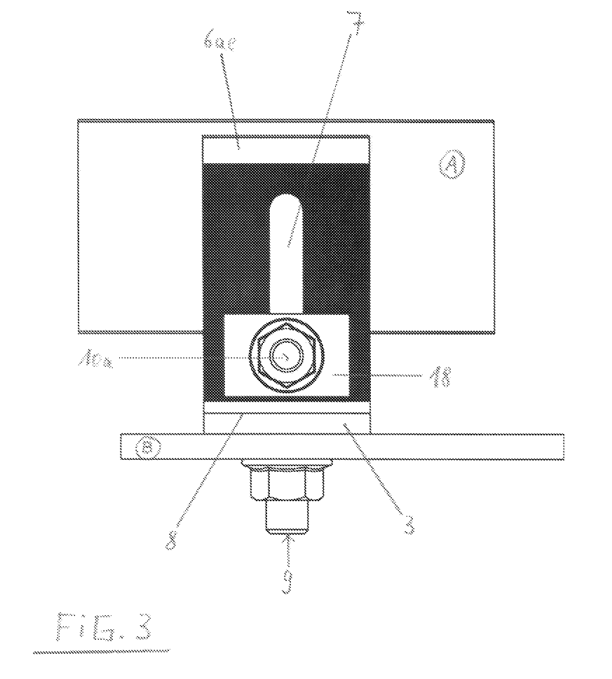

FIG. 1 shows ad advantageous embodiment of the adapter according to the invention in the inclined view, assembled on an assembly surface. FIG. 2 shows the same embodiment in the cross section and FIG. 3 on the lateral section. In addition to the support profile (A) and the assembly surface (B), FIG. 1 to FIG. 3 show in detail the following components:
1 Adapter
2 Assembly head
3 Web
4 Leg (4a, 4b)
5 Fastening clamps (5a, 5b)
6 Lateral surfaces of the legs (6a, 6b, 6ae, 6bi)
7 Openings of the legs
8 Border formed by web and leg
9 Fastening mean for the assembly head
10 Fastening mean for fastening clamps (10a, 10b)
11 Surfaces of the fastening clamps (11a, 11b) facing away the legs
12 Clearances (12a, 12b)
13 Fastening noses or fixation noses (13a, 13b)
14 Elevations or ridges (14a, 14b)
15 Bearing surface (15a, 15b)
16 Lateral surfaces of the fastening clamps (16a, 16b)
17 Leg toothing
18 Tooth wheel
19 Toothing of the tooth wheel
20 Thickening

The adapter according to the invention enables through its U-shaped design a centric acceptance of the support profile. It can be assembled easily from above. Naturally, a U-shaped design is not obligatory. The upper ends of the two legs of the assembly head can be connected with each other, with the result that the operationally connected profile rail must be pushed into the assembly head.

The adapter is equipped with at least two mounting clamps, which are advantageously pressed with screws to the side surfaces of the legs of the assembly head and thereby press and fix appropriately shaped strips of the operationally connected support profile against the legs. A direct screwing of the support profiles is thus eliminated. It is advantageous if the mounting clamps have fastening noses or fixation noses that grip into appropriate grooves of the profile rails, thereby effectively preventing, in U-shaped assembly heads, the slipping of the support profiles in direction of the U-opening. The mounting clamps are advantageously arranged in the interior of the assembly head. This ensures minimum space requirements with respect to the lateral extension of the adapter. An arrangement of the mounting clamps on the outer sides of the assembly head is also possible, provided that the grooves of the operationally connected profile rail are arranged so that they can be placed on the outer sides of the assembly head.

Particularly advantageous are mounting clamps, which, on the sides which face the legs, provided with fastening noses or fixation noses, have at least one elevation or ridge, with each having at least one bearing surface for the leg, which over the side surface of the mounting clamp have a greater height than the fastening noses or fixation noses, so that these elevations or ridges, which lie advantageously flat on the leg, act as spacers, such that between the leg and mounting clamp in the area of the fastening nose or fixation nose, a gap corresponding to the thickness of the support profile remains, even with tight screwing, and a tilting of the mounting clamp is effectively prevented.

An internal arrangement of the mounting clamps is also advantageous in combination with a preferably web-like formation of the mounting clamp at the leg-remote surface facing away from the leg, which, together with the fastening means for mounting clamps and legs, form a tight fit that fixes the fastening means. Facing away from the leg refers here to the mounting clamp on the nearest leg, not to the mounting clamps on the opposite leg. In the case of a hexagonal screw head, one of the six faces of the screw head lies on the web of the mounting clamp. This makes it advantageously possible to tighten the screw- fitting nut on the outside of the leg, without the screw being able to turn also. In such an embodiment, the mounting of the profile rail can thus take place by guiding the profile rail with its slots between leg and mounting clamps, and in a final step fixing it by tightening the outer nuts. Instead of a web, the mounting clamp can also have a screw head shaped indentation.

Before the profile rail is placed in the assembly head, the assembly head should have been connected to the roof rack. This is an advantageously centrally mounted square hole in the web, through which the extension of a roof rack can be connected, for example by using a flat head square neck bolt. Of course, otherwise shaped or several openings for fastening means in the web are also possible.

Particularly advantageous for the stability of the connection is if the mounting clamp-remote side surface of the leg is roughened in the area of the opening for the fastening means, to increase the frictional locking with the fastening means. In the case of a screw connection, the roughening can consist of a toothing or toothed washer in the surface area surrounding the opening of the leg. In the case of a screw connection, a toothed disc can then be arranged between nut and toothed surface, which has a toothing or toothed washer which complements the toothing or toothed washer of the surface. Of course, other connections than screw connections with nuts are possible. Thus, the leg can for example have an integrated thread or, instead of a screw-nut connection, a quick release connection can be used or a hole bearing fastening pin with a hole through which a slightly conical fixing pin is inserted on the leg side facing away from the clamp.

The openings in the legs are preferably identical and designed as elongated holes. Thus, a height adjustment of the mounting position of the operationally connected profile rail is possible, which especially in installation on pitched roofs is advantageous, since on the spot adjustment is possible without any problems.

The orientation of the profile rails is also changeable. The assembly head with a centric opening may, before fixation, be either rotated by means of fastening means in such a way that the edge formed by web and leg runs parallel to the roof ridge, or in such a way that this edge is aligned perpendicular to roof ridge. The alignment of the profile rails is thus equal to the alignment of the edge. As these are exposed to special forces, the profile of the assembly head in the area of this edge is advantageously designed to be additionally thick. In principle, the centric arrangement of the opening of the web allows free rotation around the central axis of the assembly head which runs perpendicular to the web.

An inclined position of the elongated holes, i.e. a positioning of their longitudinal axes in an angle of 90° to the edge formed by the web and the leg, permits a constant load of the assembly surfaces of one or more adapters, for all possible height position of the support profile, the better the force direction of the load corresponds to the longitudinal orientation of the elongated holes. Of course, the edge formed by the web and the leg should not be designed to be sharp. There are several variants possible, like more and less rounded transition areas. If an adapter for the assembly of solar modules on inclined roofs is used, advantageous adapter sets with respective inclinations of elongated holes for different roof inclinations.

This possibility to the adjustment of the inclination by respectively rotating the fastening clamps around their fastening leg in the desired way, contributes in achieving a higher variability after the adaptation of the inclination of the support profile, for instance in relation to a roof support, if an embodiment of the invention is available that permits rotation with this kind of fastening clamp. This is the case in general if the fastening clamp is equipped with precisely one preferably centrically arranged opening for the fastening means, advantageously a screw.

In addition to its optimized statics, another advantage of the adapter according to this invention is that there are minimal requirements concerning the shaping of the support profiles to be adjusted. The support profile should just be fitted with flat strips preferably equipped with slots suitable for the fastening clamps on the assembly head facing side. Otherwise there are no restrictions concerning the shaping of the support profiles. On the other hand, for assembly on the roof bearings or on other solar module bearing surfaces, it suffices if there is one essentially flat assembly surface with an opening, preferably with a centrally arranged clearance. In this case an opening means continuous holes or even deepening points within a surface, while clearances, as a special form of opening, exclusively mean continuous holes.

1-20. (canceled)

21. Adapter for support profiles, in particular for support arrangements for solar modules, comprising:
an assembly head for the acceptance of the support profile which is equipped at least with two opposite legs connected one with another by at least one web,
and with at least two fastening clamps connected with the assembly head for the acceptance support profile.

22. Adapter according to claim 21,
wherein,
the at least two fastening clamps are arranged on the lateral surfaces of the legs.

23. Adapter according to claim 21,
wherein,
the at least two fastening clamps are arranged within the assembly head.

24. Adapter according to claim 21,
wherein,
the two opposite legs are respectively equipped with at least one opening.

25. Adapter according to claim 24,
wherein,
openings of the legs as elongated holes.

26. Adapter according to claim 25,
wherein,
the longitudinal axes of the elongated holes of the opposite legs are arranged in an angle of 90° from the border formed by the web and the leg.

27. Adapter according to claim 24,
wherein,
at least two of the opposite legs are equipped with at least one opening of the same shape and extension.

28. Adapter according to claim 24,
wherein,
the openings and surfaces of the legs are congruent in the overview, wherein the overview of the external surface of a leg is congruent with the overview of the internal surface of the opposite leg.

29. Adapter according to claim 21,
wherein,
the web is equipped with at least one clearance for a connection mean for the assembly of the assembly head on an assembly surface.

30. Adapter according to claim 29,
wherein,
the clearance of the web is designed as centrically arranged four-border-hole.

31. Adapter according to claim 21,
wherein,
the fastening clamps are respectively equipped with at least one clearance for a fastening means.

32. Adapter according to claim 21,
wherein,
at least one screw-mediated effective connection between the fastening clamp and a leg of the assembly head.

33. Adapter according to claim 21,
wherein,
the surface facing away the leg of the fastening clamp is equipped at least with one molding which form a shape conclusion with the connection mean.

34. Adapter according to claim 21,
wherein,
the fastening clamps are equipped with at least one fixation nose at a certain distance from the leg surface for the engagement into a support profile.

35. Adapter according to claim 21,
wherein,
the fastening clamps on their parts facing the legs are equipped with at least one ridge with at least one respective bearing surface for the leg.

36. Adapter according to claim 34,
wherein,
the fixation nose and the bearing surface of the fastening clamps are arranged on the same lateral surface facing the leg of the fastening clamp and that the distance of the bearing surface to the lateral surface is larger than the height of the fixation nose over this lateral surface.

37. Adapter according to claim 21,
wherein,
the surfaces facing away from the fastening clamps of the legs are roughened in the surfaces adjacent to the clearances.

38. Adapter according to claim 37,
wherein,
the roughened areas are equipped with a toothing.

39. Adapter according to claim 32,
wherein,
the screw-mediated effective connection is equipped with a toothed washer with a complementary toothed washer to the toothed washer of the leg.

40. Adapter according to claim 21,
wherein,
the profile of the assembly head is equipped with thickenings on the passages from the web to the legs.
